(19) United States
(12) Patent Application Publication
(10) Pub. No.: US 2003/0090339 A1
(43) Pub. Date: May 15, 2003

(54) Digitally controllable integrated filter circuit for high frequency application

(76) Inventors: Hyun Kyu Yu, Taejon (KR); Seon-Ho Han, Wonju-Si (KR); Mun Yang Park, Taejon (KR); Seong-Do Kim, Taejon (KR); Piljae Park, Gyeongsan-Si (KR); Nam-Soo Kim, Seoul (KR); Cheon Soo Kim, Taejon (KR); Yong-Sik Youn, Taejon (KR)

Correspondence Address: BLAKELY, SOKOLOFF, TAYLOR & ZAFMAN LLP, Seventh Floor, 12400 Wilshire Boulevard, Los Angeles, CA, 90025, US

(21) Appl. No.: 10/033,418

(22) Filed: Dec. 28, 2001

(30) Foreign Application Priority Data
Nov. 14, 2001 (KR) 2001-70752

(51) Int. Cl. H03H 7/00

(52) U.S. Cl. 333/167

(57) ABSTRACT

The present invention relates to an integrated filter circuit for digitally controlling characteristics of inductor and capacitor to thereby produce a controlled resonant frequency. The integrated circuit includes a number of inductors being connected in series between a high frequency input node and a high frequency output node, a plurality of capacitors each connected to a connection node of said each inductors, a plurality of switches, each connected between each capacitor and a ground and a feedback control unit for controlling the switches by sensing an output signal from the high frequency output node to thereby selectively couple each capacitor to the ground through a selected switches based on the sensed output signal.

### FIELD OF THE INVENTION

The present invention relates to an integrated filter circuit; and, more particularly, to an integrated filter circuit and having a resonant circuit, which includes digitally a controllable inductor and capacitor to thereby effectively produce a controlled resonant frequency thereof.

### DESCRIPTION OF THE PRIOR ARTS

A resonance means that amplitude of oscillation of a vibroscope becomes maximized when a natural frequency thereof is equal or very close to a frequency from an external. A tuning is a method for controlling the frequency to produce the resonance. A resonant circuit is generally used in a filter circuit and generally includes an inductor L and a capacitor C controlling a resonant frequency. By controlling L or C, a resonant frequency of the resonant circuitry can be adjusted. Specially, a parallel type resonant circuit is used as a turning circuit for a telecommunication apparatus and an electric instrument including a television set and a radio.

In a graph denoting changes of a frequency or a current around the resonance frequency, a current of a series type resonant circuit becomes the maximum value and a current of the parallel type resonance circuit becomes the minimum value, closing to 0.

On the other hand, in case of measuring the resonant frequency a lead line for the measurement usually contains an inductance or a stray capacity so a value of the inductance or the stray capacity is unnecessarily added to the resultant value of the measurement in the resonant circuit. That is, the inductance and the stray capacity of the lead line cause on the resonant frequency the deviation. Such a deviation is easier to be generated at higher frequency. An integration technique of an inductor or a capacitor, for use in the LC resonant circuit, has been rapidly developed. That is, a poly-silicon capacitor has been used as an integrated capacitor in a semiconductor manufacturing process, however, as developing a multi-layer metal wiring technique, it becomes possible to use a metal insulator metal (MIM) in the semiconductor manufacturing process.

Referring to FIG. 1, a conventional N-layer lowpass filter contains inductors L₂ to L₂ₙ connected between a high frequency input node RFᵢₙ and a high frequency output node RFₒᵤₜ in series. The conventional N-layer lowpasss filter further includes capacitors C₁ to C₂ₙ₊₁ each connected between node N₁ to N₂ₙ₊₁ and a ground, wherein n is 0 to n.

The conventional N-layer lowpass filter having the above configuration is generally integrated on a semiconductor substrate. In this case, in order to produce a resonant frequency, there are several provided methods for integrating the conventional N-layer lowpass filter such as a method for trimming capacitors, a technique for hard-wired tuning by adjusting a wire configuration on multi-layer and a process for attachable/detachable LC elements. However, it is very hard to obtain appropriate result by un-known variables caused. by an integration process or the difference between operational characteristics of elements in case where such a conventional integration methods are performed. Therefore, the conventional integration of the conventional N-layer lowpass filter gives inconvenience and problems.

### SUMMARY OF THE INVENTION

It is, therefore, an object of the present invention to provide an integrated filter circuit for digitally controlling characteristics of inductor and capacitor to thereby produce a controlled resonant frequency.

It is another object of the present invention to provide an integrated filter device for effectively providing optimized efficiency and integration thereof.

In accordance with an aspect of the present invention, there is provided a integrated filter circuit, including a number of inductors being connected in series between a high frequency input node and a high frequency output node; a plurality of capacitors each connected to a connection node of said each inductors; a plurality of switches, each connected between each capacitor and a ground; and a feedback control unit for controlling the switches by sensing an output signal from the high frequency output node to thereby selectively couple each capacitor to the ground through a selected switches based on the sensed output signal.

In accordance with other aspect of the present invention, there is provided an integrated filter device, including a feedback control unit; a switching unit; and a L C circuit having a coiled strip line arranged on an insulator of a semiconductor substrate where the coiled strip includes a number of inductors and a plurality of capacitor connected to the inductors. Each capacitor contains a first conductor being connected to the switching unit; a dielectric layer being stacked on the first conductor layer; a second electrode conductor being stacked on the dielectric layer; and a second conductor layer being connected to one electrode of each conductor.

### BRIEF DESCRIPTION OF THE DRAWINGS

The above and other objects and features of the present invention will become apparent from the following description of the preferred embodiments given in conjunction with the accompanying drawings, in which:

FIG. 1 is a circuit diagram of conventional LC type N-layer lowpass filter;

FIG. 2 is a circuit diagram of an integrated filter circuit for high frequency application in accordance with one embodiment of the present invention;

FIG. 3 is a diagram of an integrated filter device in accordance with another embodiment of the present invention;

FIG. 4 is a detailed diagram for illustrating the LC circuit in FIG. 3; and

FIG. 5 is a cross sectional view of z to z′ of FIG. 4.

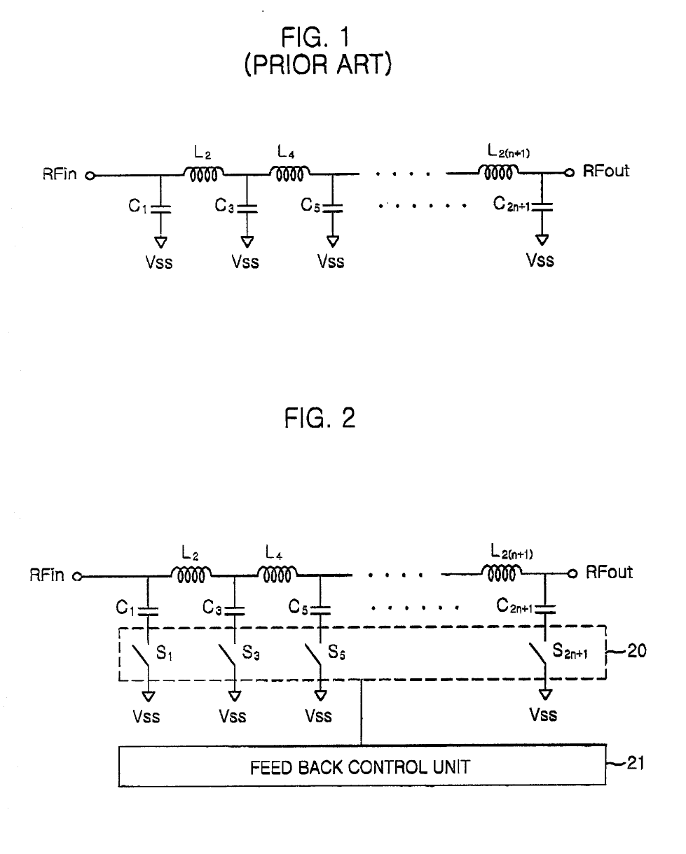

### DETAILED DESCRIPTION OF THE INVENTION

FIG. 2 is a circuit diagram of an integrated filter circuit for high frequency application in accordance with one preferred embodiment of the present invention.

As shown, the integration circuit is provided with a high frequency input node RFᵢₙ, a high frequency output node RFₒᵤₜ, a number of inductors L₂ to L₂₍ₙ₊₁₎, a plurality of capacitors C₁ to C₂ₙ₊₁, a switch unit 20, and a feedback control unit 21. The inductors L₂ to L₂₍ₙ₊₁₎ are connected in series between the high frequency input node RFᵢₙ and the high frequency output node RFₒᵤₜ, wherein n is 0 to n. One of two terminals of each capacitor C₁ to C₂ₙ₊₁ is connected to a node N₁ to N₂ₙ₊₁. The switch unit 20 is connected to other terminal of each capacitor C₁ to C₂ₙ₊₁ and a ground Vₛₛ. The feedback control unit 21 receives a signal from the high frequency output node RFₒᵤₜ and generates a control signal for controlling the switch unit 20 to provide the signal to the switch unit 20. That is, the output signal from the high frequency node RFₒᵤₜ is provided to the feedback control unit 21 in order to control the switch unit 20.

The switch unit 20 includes switches S₁ to S₂ₙ₊₁. One of two terminals of each switch S₁ to S₂ₙ₊₁ is connected to a ground Vₛₛ and the other terminal is connected to each capacitor C₁ to C₂ₙ₊₁. The switches in the switch unit 20 can be individually controlled by the feedback control unit 21. A transistor is used for the switch in the switch unit 20. A gate of the transistor is controlled by the feedback control unit 21.

The feedback control unit 21 controls an on/off operation of each switch in the switch unit 20 in digital mode. That is, the feedback control unit 21 receives the output signal from the high frequency output end RFₒᵤₜ and modifies the output signal to generate a digital control signal to be the coupled to the switch unit 21 based on the modified output signal.

Above-mentioned inductors L₂ to L₍₂ₙ₊₁₎ and switches S₁ to S₂ₙ₊₁ using the capacitors C₁ to C₂ₙ₊₁ as an intermedium are combined as an N-layer lowpass filter.

Operations of the integrated filter circuit will be described in detail herein after.

For an example, lets considering an integrated filter circuit has only C₁, C₃, C₅ and S₁, S₃, S₅ or L₂, L₄. If all switches are turned on except S₃, the C₃ is not operated as a capacitor and L₂ and L₄ becomes connected in series to change the inductance of the integrated filter circuit. According to states of the switches S₁, S₃ and S₅, the capacitors Cₗ, C₃ and C₅ and inductors L₂ and L₄, the resonant frequency will change. In case an N-layer LC type filter, numerous on/off combinations of switches can be provided so that various resonant frequency will be produced.

In other word, by using the switches S₁ to S₂ₙ₊₁ each capacitor C₁ to C₂ₙ₊₁ is selectively coupled to the ground to thereby control the resonant frequency outputted from the high frequency output end RFₒᵤₜ.

Therefore, in accordance with the present invention by using selectively and digitally attachable capacitors to the integrated filter circuit, a controlled resonant frequency can be produced without physically replacing LC elements for gaining a desired resonance frequency.

By using the selectively and digitally controllable capacitor with an integration technique, an integrated programmable LC resonance circuit or a programmable filter circuit can be easily implemented in accordance with the present invention.

In concrete way, metal insulator metal (MIM) capacitors C₁ to C2n+1₋₁ are arranged at predetermined portion of integrated inductors L₂ to L₂ₙ, The MIM capacitors C₁ to C₂ₙ₊₁ are connected to switches S₁ to S₂ₙ₊₁. The feedback control unit 21 decides operations of switches S₁ to S₂ₙ₊₁. The feedback control unit 21 receives the output signal RFₒᵤₜ and has pre-programmed data stored in an storage unit such as a RAM or ROM. The feedback control unit 21 produces a digital code based on the output signal RFₒᵤₜ and the pre-programmed data for controlling the switches contained in the switch unit 51. Therefore, a desired resonant frequency can be generated by controlling switches based on the digital code.

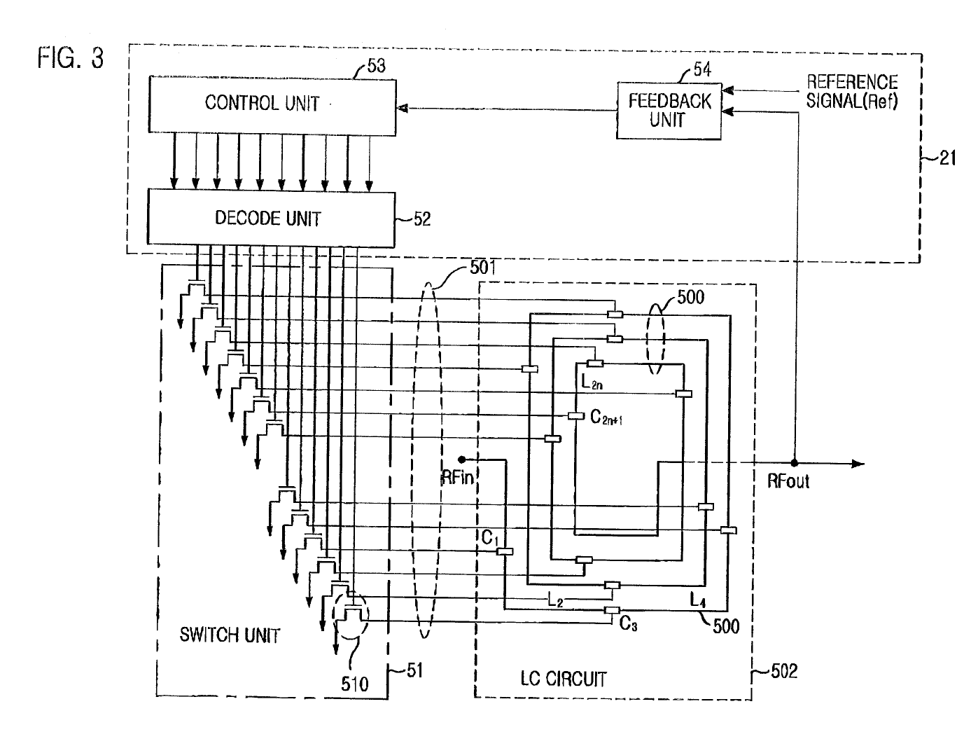

FIG. 3 is a schematic diagram of an integrated filter device in accordance with the preferred embodiment of the present invention.

As shown, the integrated semiconductor device has a feedback control unit 21, a switch unit 51 and a LC circuit 502.

The feedback control unit 21 shown in FIG. 3 has the same structure and functions with the feedback control unit 21 shown in FIG. 2 The feedback control unit 21 is provided with a decode unit 52, a control unit 53 and a feedback unit 54. The feedback unit 54 is connected to the control unit 53 and receives the output signal RFₒᵤₜ and a reference the signal R_{ef}. The feedback unit 54 compares the output signal RFₒᵤₜ with the reference signal R_{ef} and transmits a comparison result to the control unit 53. The control unit 53 is connected to the decode unit 52. The control unit 53 determines a combination of on/off states of switches according to the result and outputs a signal to the decode unit 52. The decode unit 52 is connected to the switch unit 51 and generates a decoded control signal for controlling an on/off operation of each switch provided in the switch unit 51.

The switch unit 51 includes transistors 510 as switches. One of two terminals of each transistor is connected to a ground Vₛₛ and the other terminal is connected to each capacitor C₁ to C_{2n +1}. The transistors in the switch unit 51 can be individually controlled by the feedback control unit 21.

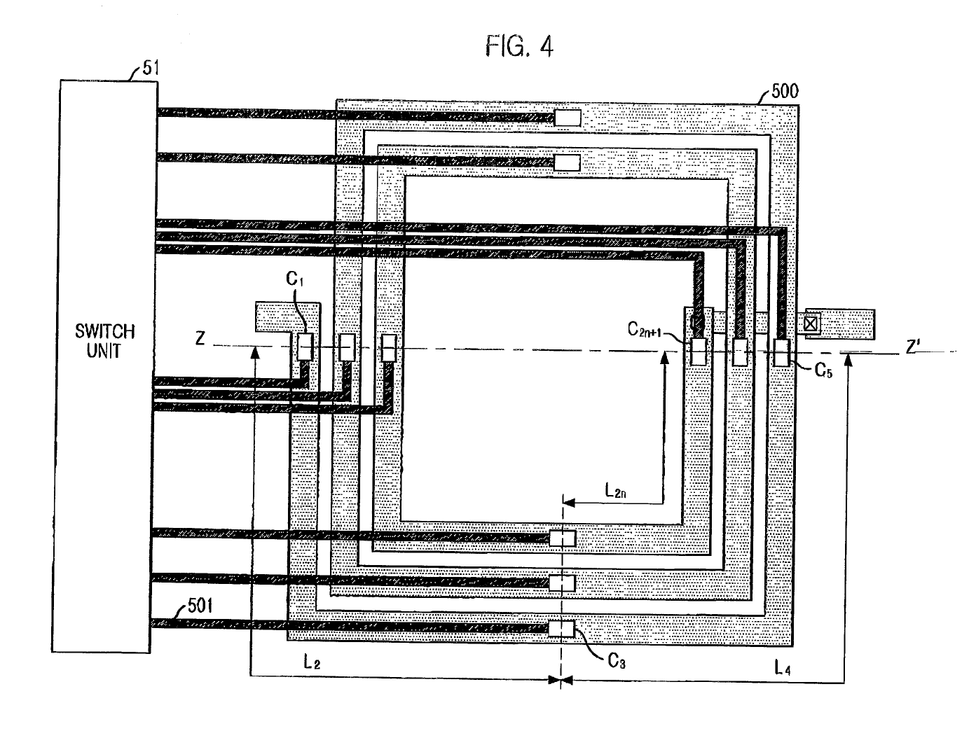

FIG. 4 is a detailed diagram for illustrating the switch unit and the LC circuit shown in FIG. 3.

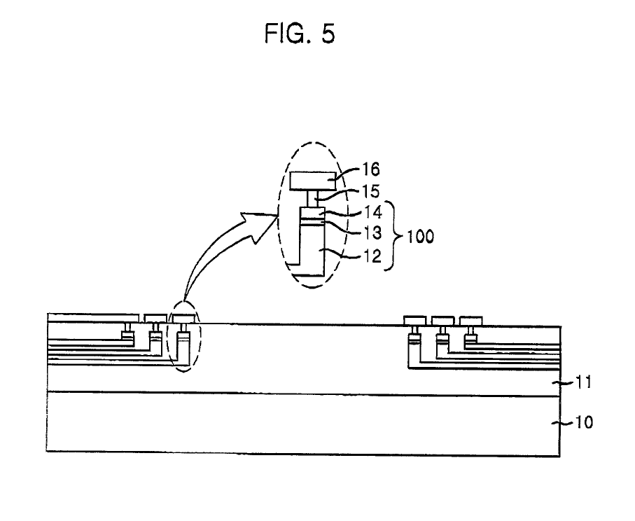

As shown, the integrated high frequency filter device contains the switch unit 51, a coiled strip line 500, electrode lines 501 and capacitors C₁ to C₂ₙ₊₁. The coiled wire 500 is deposited on an insulator of the semiconductor circuit board as a coil form. The electrode wires 501 connect the switch unit 51 to capacitors C₁ to C₂ₙ₊₁. A spatial structure of each capacitor C₁ to C₂ₙ₊₁ is described in detail in FIG. 5 as a capacitor 100.

FIG. 5 is a cross sectional view of Z ‘to Z’ of FIG. 4. As shown, the capacitor 100 includes a first conductive layer 12, a dielectric layer 13 and a second conductive layer 14. The first conductive layer 12 is connected to the switch unit 51 and is electrode of the capacitor 100. The dielectric layer 13 is stacked on the first conductive layer 12. The second electrode conductor layer 14 is deposited on the dielectric layer 13 as the other upper electrode of the capacitor 100. The connector 15 serves electrically to connect the second conductive layer 14 to the third conductive layer 16. The third conductor layer 16 is one of two electrode of an inductor.

As described above, the capacitor 100 has the Metal Insulator Metal (MIM) structure and is combined with the third conductive layer 16 of a parallel inductor circuit.

Referring again to FIGS. 4 and 5, the control unit 53 outputs a control signal for controlling to the switch unit 51 through the decode unit 52. Each switch in the switch unit 51 is connected between each capacitor and ground, so that each capacitor becomes turned on or off by the control signal. The capacitors C₁ to C₂ₙ₊₁ are controlled by switches in the switch unit 51. Therefore, according to the control signal, each of capacitors C₁ to C₂ₙ₊₁ becomes connected or disconnected with the inductors L₂ to L₂ₙ. As a result, an inductance of the integrated filter circuit according to each inductor L₂ to L₂ₙ can be changeable by connecting/disconnecting each capacitor C₁ to C₂ₙ₊₁ to the grounds. According to such above-mentioned operations, an output frequency can be adjusted and, therefore, a wanted resonant frequency can be obtained.

Above-mentioned operation steps will be described in detailed with an example as herein below.

The feedback unit 54 receives the output signal RFₒᵤₜ and a reference signal R_{ref} and compares the RFₒᵤₜ and the R_{ref} and an integrator in the feedback unit 54 determines the difference between the RFₒᵤₜ and the R_{ref}. By using the comparator and the integrator in the feedback unit 54, the difference of the RFₒᵤₜ and R_{ref} signal is transformed to an electrical signal having a value. The electric signal is the transmitted to the control unit 53 and an analog-to-digital converter in the control unit 53 converts the electric signal to a digital control signal having a specific number of bits.

The digital control signal is transmitted to the decode unit 52 and the decode unit 52 generates a specific code representing the received digital control signal. The specific code controls on/off operations of transistors connected to node of the capacitors to thereby disconnect selected capacitor from the LC resonant circuit. By above-mentioned operations, characteristics of a filter are effectively controlled.

By combining a digital control circuit with an in-board capacitor, a resonant frequency of a filter or a resonant circuit can be controlled efficiently. And also programmable integrated LC circuit can be easily implemented and an efficiency of a circuit can be optimized.

While the present invention has been described with respect to certain preferred embodiments, it will be apparent to those skilled in the art that various changes and modifications may be made without departing from the scope of the invention as defined in the following claims.

What is claimed is:

1. An integrated circuit, comprising:
a number of inductors being connected in series between a high frequency input node and a high frequency output node;
a plurality of capacitors each connected to a connection node of said each inductors;
a switching means, each connected between each capacitor and a ground; and
a feedback control means for controlling the switches by sensing an output signal from the high frequency output node to thereby selectively couple each capacitor to the ground through a selected switches based on the sensed output signal.

2. The integrated circuit as recite in claim 1, wherein, said feedback control means includes:
a feedback unit for sensing an output signal from the high frequency output node and comparing the sensing signal with a reference signal to generate a comparison;
a control unit for receiving the comparison signal to generate a control signal based on the comparison signal; and
a decode unit for generating a decided control signal in response to the control signal.

3. The integrated circuit as recite in claim 1, wherein, said switching means being connected between the ground and the capacitors includes a plurality of switching transistors and the transistors are controlled by said feedback control means.

4. An integrated filter device, including:
a feedback control means;
a switching means; and
a L C circuit having a coiled strip line arranged on an insulator of a semiconductor substrate where the coiled strip includes a number of inductors and a plurality of capacitor connected to the inductors.

5. The integrated filter circuit as recited in claim 4, wherein said feedback control means includes:
a feedback unit for sensing an output signal from the high frequency output node and comparing the sensing signal with a reference signal to generate a comparison;
a control unit for receiving the comparison signal to generate a control signal based on the comparison signal; and
a decode unit for generating a decided control signal in response to the control signal.

6. The integrated filter circuit as recited in claim 4, wherein, said switching means being connected between the ground and the capacitors includes a plurality of switching transistors and the transistors are controlled by said feedback control means.

7. The integrated filter circuit as recited in claim 4, wherein said capacitors comprises:
a first conductor being connected to the switching unit;
a dielectric layer being stacked on the first conductor layer;
a second electrode conductor being stacked on the dielectric layer; and
a second conductor layer being connected to one electrode of each conductor.

8. The integrated filter device as recited in claim 4, wherein said capacitor has metal insulator metal (MIM) structure.

9. The integrated filter circuit as recited in claim 7, wherein said second conductor layer is connected to the coiled strip type inductor.
